(19) United States
(12) Patent Application Publication
(10) Pub. No.: US 2025/0180992 A1
(43) Pub. Date: Jun. 5, 2025

(54) DEPOSITION OF RESIST UNDERLAYER FOR ENHANCING PHOTORESIST PERFORMANCE

(71) Applicant: Applied Materials, Inc., Santa Clara, CA (US)

(72) Inventors: Guangyan ZHONG, Santa Clara, CA (US); Sudha RATHI, San Jose, CA (US); Pramit MANNA, Santa Clara, CA (US); Abhijit B. MALLICK, Fremont, CA (US)

(21) Appl. No.: 18/524,466

(22) Filed: Nov. 30, 2023

(51) Int. Cl. G03F 7/11; C09D 183/08

(52) U.S. Cl. CPC G03F 7/11; C09D 183/08

(57) ABSTRACT

The present disclosure generally relate to the field of semiconductor processing and, in particular, to methods of forming a resist underlayer for use in EUV lithography processing. In some embodiments, the present disclosure provides a method for forming a resist underlayer having improved adhesion using a resist underlayer agent. In some embodiments, the resist underlayer is formed using the resist underlayer agent in a UV-assisted deposition process.

### BACKGROUND

### Field

Embodiments of the present disclosure generally relate to the field of semiconductor processing and, in particular, to methods of forming a resist underlayer for use in EUV lithography processing.

### Description of the Related Art

As geometries of the electronic devices shrink, lithography and patterning for electronic device designs become more challenging. A single lithographic exposure may not be enough to provide sufficient resolution. Typically, for manufacturing integrated circuits (ICs), multiple patterning techniques and additional metal layers are used to increase the feature density. The multiple-patterning techniques and implementation of the additional metal layers complicate the manufacturing technology and are expensive.

The demands for greater integrated circuit densities also impose demands on the process sequences used in the fabrication of integrated circuit components. For example, process sequences that employ conventional lithography techniques for semiconductor device manufacturing employs primarily four operations. These operations include (1) photoresist or “resist” coating; (2) exposure; (3) wet development; and (4) etch. The photoresist coating may include a layer of energy sensitive resist formed over a stack of material layers deposited on a substrate. The energy sensitive resist layer is exposed to an image of a pattern to form a photoresist mask. Thereafter, the mask pattern is transferred to one or more of the material layers of the stack using an etch process. The chemical etchant used in the etch process is selected to have a greater etch selectivity for the material layers of the stack than for the mask of energy sensitive resist. That is, the chemical etchant etches the one or more layers of the material stack at a rate much faster than the energy sensitive resist. The etch selectivity to the one or more material layers of the stack over the photoresist prevents the energy sensitive photoresist from being consumed prior to completion of the pattern transfer.

Generally, extreme ultraviolet (EUV) lithography uses EUV wavelength that is much shorter than the wavelengths of the conventional techniques to scale down the feature sizes on the IC chips. Typically, the EUV lithography uses the EUV resist patterned using a EUV wavelength that is about 13.5 nm. The EUV resist, however, is much less resistant to etching than the photoresist used for conventional patterning techniques. Currently, the integrity of the EUV resist pattern resulted from etching is very poor comparing to that of the conventional photoresists. To use EUV lithography to form features on a substrate, a resist underlayer is typically deposited on a substrate, and then an EUV photoresist is deposited over the resist underlayer. As the feature size of the device decreases, the resist underlayer may preferably be thinner to allow the formation of etched features with a desired resolution or aspect ratio.

Several properties are important in lithography processes. Such important properties include sensitivity, resolution, lower line-edge roughness (LER), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films. Thinner films increase the efficiency of the lithographic process.

The lithography processes described above may suffer from several drawbacks. For instance, wet development of resists may produce a pattern having resist line-edge-roughness (LER) due to an acid gradient at mask edges. This may cause uncertainty in predicting line edges that result following wet development. High aspect ratio patterns are also increasingly being utilized to improve resist roughness performance and provide more etch resistance to allow a wider margin of etch transfer. However, high aspect ratio patterns can also increase the tendency for pattern collapse. As device dimensions shrink, capillary forces due to the small feature size may cause pattern collapsing during wet development and cleaning processes. To enable further miniaturization of resist pattern transfer for EUV lithography, addressing pattern collapse of the photoresist is important. Although capillary force may be a main cause of pattern collapse, other factors that can also influence pattern collapse include the adhesion force between the photoresist and the substrate.

The demand for ever-decreasing feature sizes has also led to the use of thinner films to prevent pattern collapse. Accordingly, the thickness of the energy sensitive EUV photoresist may correspondingly be reduced in order to control pattern resolution. However, when thin photoresist are used, the EUV photoresist alone might not capture an adequate EUV exposure dose. A resist underlayer is therefore often used between the energy sensitive EUV photoresist and the underlying substrate material layers to help facilitate pattern transfer. Resist underlayers can also assist pattern transfer by smoothing out surface feature roughness of a substrate thereby improving exposure results. Resist underlayers can also contribute to improving EUV exposure results by normalizing the surface energy and increasing photoresist adhesion, both of which may assist in reducing the risk of pattern collapse. However, although a dense underlayer can improve selectivity by offering a strong contrast to the EUV photoresist, a dense underlayer also etches more slowly thereby increasing the resist's exposure to the etch chemistry. If the EUV photoresist is too thin, the photoresist can erode away before the etch is complete. As such, as the EUV photoresist thickness decreases, underlayer thickness should decrease too.

Accordingly, there is a need in the art for improved thin resist underlayers with increased photoresist adhesion to reduce pattern collapse and methods for forming the same.

### SUMMARY

Embodiments described herein generally relate to methods for forming a resist underlayer with increased photoresist adhesion on a substrate for use in EUV lithography processes. In one embodiment, a method for forming a resist underlayer on a substrate is provided. The method includes exposing the substrate to a resist underlayer agent to deposit the resist underlayer over a top surface of the substrate, wherein the resist underlayer agent comprises a chemical compound having a general structure

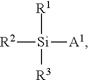

wherein R¹, R², and R³ are hydrocarbon functional groups each with a general formula CₓH_{y} in which x has a range of between 1 and 8 and y has a range of between 1 and 17, and A¹ is a hydrogen atom, chlorine atom, bromine atom, iodine atom, or an amine group.

In another embodiment, a method for forming a resist underlayer on a substrate is provided. The method includes exposing a substrate to UV radiation in an atmosphere of a resist underlayer agent to deposit the resist underlayer over a top surface of the substrate, wherein the resist underlayer agent comprises a chemical compound having a general structure

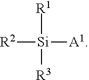

In some embodiments of the resist underlayer agents, R¹, R², and R³ are hydrocarbon functional groups each with a general formula CₓH_{y} in which x has a range of between 1 and 8 and y has a range of between 1 and 17, and A¹ is a hydrogen or an amine group comprising at least one hydrocarbon functional group with a general formula CₓH_{y} in which x has a range of between 1 and 8 and y has a range of between 1 and 17.

In yet another embodiment, a method for forming a resist underlayer on a substrate within a process chamber is provided. The method includes positioning a substrate in a processing a processing region of the process chamber and flowing a resist underlayer agent into the processing region, wherein the resist underlayer agent comprises a chemical compound having a general structure

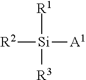

in which R¹, R², and R³ are hydrocarbon functional groups each with a general formula CₓH_{y} in which x has a range of between 1 and 8 and y has a range of between 1 and 17, and A¹ is a hydrogen or an amine group. The method also includes exposing the substrate to the resist underlayer agent to deposit the resist underlayer over a top surface of the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a partial cross-sectional section view of a process chamber, according to certain embodiments of the present disclosure;

FIG. 2 is a schematic isometric cross-sectional view of a portion of the process chamber in FIG. 1, according to certain embodiments of the present disclosure;

FIG. 3 is a schematic cross-sectional view of the process chamber in FIG. 2 illustrating a gas flow path, according to certain embodiments of the present disclosure;

FIG. 4 is a process flow diagram depicting a method for forming a resist underlayer using a resist underlayer agent in a deposition process, according to certain embodiments described herein;

FIG. 5 is a process flow diagram depicting a method for forming a resist underlayer using a resist underlayer agent in a UV-assisted deposition process, according to certain embodiments described herein;

FIG. 6 is a table depicting changes in carbon composition of a substrate by resist underlayers formed in accordance with certain embodiments described herein;

FIG. 7 is a table depicting changes surface energy of a substrate by resist underlayers formed in accordance with certain embodiments described herein; and

FIG. 8 is a table depicting changes adhesive work between a photoresist and a substrate due to resist underlayers formed in accordance with certain embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Methods of forming a resist underlayer on a substrate for use in EUV lithography processes are described herein. In the following description, numerous specific details are set forth in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to processing directly on the surface of the substrate itself, in the present disclosure, any of the processing steps disclosed may also be performed on an intermediate layer formed on the substrate as disclosed in more detail below, and the term “substrate surface” is intended to include such intermediate layer as the context indicates. Thus, for example, where a film/layer or partial film/layer has been deposited onto a substrate surface, the exposed surface of the newly deposited film/layer becomes the substrate surface.

To provide context, as feature and device sizes decrease, the stack thickness is correspondingly reduced. As such, the resist underlayer may preferably also be thinner to allow the formation of etched features with a desired resolution and/or aspect ratio. As the thickness of the underlayer resist film decreases, the adhesion at the interface between the resist underlayer and the EUV photoresist can decrease due to mis-matched surface energies between the two materials. Poor adhesion between the resist underlayer and the EUV photoresist can result in poor line width roughness (LWR), line pattern collapse (LPC), and/or other lithography related defects.

The present disclosure provides a method for forming a resist underlayer having improved adhesion between the resist underlayer and the EUV photoresist disposed thereon using a UV-assisted deposition process to form the resist underlayer. During the UV-assisted deposition process, a gaseous or vaporized resist underlayer agent is introduced into a process chamber along with a carrier gas, such as He or Ar. UV light may then be used to activate the resist underlayer agent and form an ultrathin single molecular underlayer over the substrate. In various embodiments, the resist underlayer agent may contain a compound that bonds with the OH molecules on the surface of the substrate (e.g., SiOx surface of silicon substrate) thereby reducing the polar groups of the SiOx surface. The treatment with the resist underlayer agent may correspondingly also increase the number of surface carbon-hydrogen based functional groups on the surface of the substrate thereby enabling higher coverage of the substrate and modifying the surface energy thereof for increased adhesive work towards the EUV photoresist. Various embodiments of the present disclosure are discussed below in more detail.

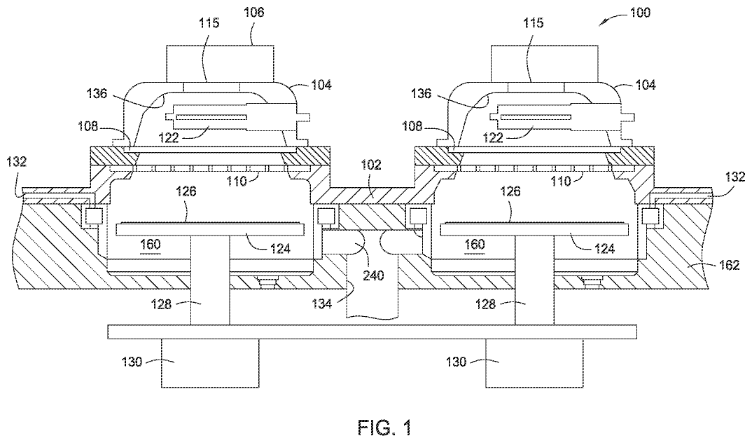

FIG. 1 illustrates a cross-sectional view of an exemplary tandem process chamber 100 that may be used to perform the methods disclosed herein, in accordance with certain embodiments. The process chamber 100 provides two separate and adjacent processing regions in a chamber body for processing the substrates. The process chamber 100 has a lid 102, housings 104 and power sources 106. Each of the housings 104 cover a respective one of two UV lamp bulbs 122 disposed respectively above two processing regions 160 defined within the body 162. Each of the processing regions 160 includes a heating substrate support, such as substrate support 124, for supporting a substrate 126 within the processing regions 160. The UV lamp bulbs 122 emit UV light that is directed through the windows 108 and showerheads 110 onto each substrate located within each processing region. The substrate supports 124 can be made from ceramic or metal such as aluminum. The substrate supports 124 may couple to stems 128 that extend through a bottom of the body 162 and operated by drive systems 130 to move the substrate support 124 in the processing regions 160 toward and away from the UV lamp bulbs 122. The drive systems 130 can also rotate and/or translate the substrate supports 124 during curing to further enhance uniformity of substrate illumination. The exemplary tandem process chamber 100 may be incorporated into a processing system, such as a Producer™ processing system, commercially available from Applied Materials, Inc., of Santa Clara, California.

The UV lamp bulbs 122 can be an array of light emitting diodes or bulbs utilizing any of the state of the art UV illumination sources including, but not limited to, microwave arcs, radio frequency filament (capacitively coupled plasma) and inductively coupled plasma (ICP) lamps. Various concepts for enhancing uniformity of substrate illumination include use of lamp arrays which can also be used to vary wavelength distribution of incident light, relative motion of the substrate and lamp head including rotation and periodic translation (sweeping), and real-time modification of lamp reflector shape and/or position. The UV bulbs are a source of ultraviolet radiation, and may transmit a broad spectral range of wavelengths of UV and infrared (IR) radiation.

The UV lamp bulbs 122 may emit light across a broad band of wavelengths from 170 nm to 400 nm. The gases selected for use within the UV lamp bulbs 122 can determine the wavelengths emitted. UV light emitted from the UV lamp bulbs 122 enters the processing regions 160 by passing through windows 108 and gas distribution showerheads 110 disposed in apertures in the lid 102. The windows 108 may be made of an OH free synthetic quartz glass and have sufficient thickness to maintain vacuum without cracking. The windows 108 may be fused silica that transmits UV light down to approximately 150 nm. The showerheads 110 may be made of transparent materials such as quartz or sapphire and positioned between the windows 108 and the substrate support 124. Since the lid 102 seals to the body 162 and the windows 108 are sealed to the lid 102, the processing regions 160 provide volumes capable of maintaining pressures from approximately 0.5 Torr to approximately 650 Torr. Processing or cleaning gases may enter the processing regions 160 via a respective one of two inlet passages 132. The processing or cleaning gases then exit the processing regions 160 via a common outlet port 134.

Each of the housings 104 includes an aperture 115 adjacent the power sources 106. The housings 104 may include an interior parabolic surface defined by a cast quartz lining 136 coated with a dichroic film. The dichroic film usually constitutes a periodic multilayer film composed of diverse dielectric materials having alternating high and low refractive index. Therefore, the quartz linings 136 may transmit infrared light and reflect UV light emitted from the UV lamp bulbs 122. The quartz linings 136 may adjust to better suit each process or task by moving and changing the shape of the interior parabolic surface.

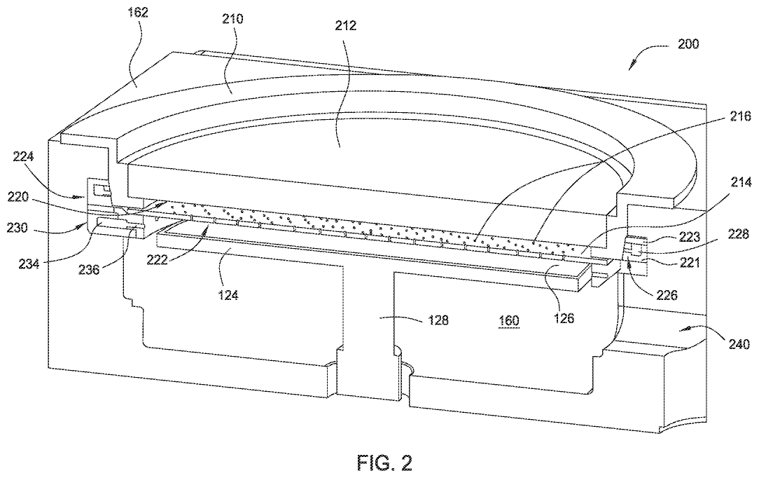

FIG. 2 shows a schematic isometric cross-sectional view of a portion of a process chamber 200, which may be used alone, or in place of any of the processing region of the tandem process chamber 100. The design of hardware shown in FIG. 2 enables a specific gas flow profile distribution across the substrate 126 being processed in a UV chamber, lamp heated chamber, or other chamber where light energy is used to process a film or catalyze a reaction, either directly on or above the substrate 126.

A window assembly is positioned within the process chamber 200 to hold a first window, such as a UV vacuum window 212. The window assembly includes a vacuum window clamp 210 that may be directly or indirectly rested on a portion of the body 162 (FIG. 1) and supports a vacuum window 212 through which UV light may pass from the UV lamp bulbs 122. The vacuum window 212 is generally positioned between the UV radiation source, such as UV lamp bulbs 122, and the substrate support 124. A showerhead 214, which may be formed of various transparent materials such as quartz or sapphire, is positioned within the processing region 160 and between the vacuum window 212 and the substrate support 124. The transparent showerhead 214 forms a second window through which UV light may pass to reach the substrate 126. The transparent showerhead defines an upper processing region 220 between the vacuum window 212 and transparent showerhead 214 and further defines a lower processing region 222 between the transparent showerhead 214 and the substrate support, such as substrate support 124. The transparent showerhead 214 also has one or more passages 216 between the upper and lower processing regions 220, 222. The passages 216 may have a roughened internal surface for diffusing the UV light so there is no light pattern on the substrate 126 during processing. The size and density of the passages 216 may be uniform or non-uniform to effectuate the desired flow characteristics across the substrate surface. The passages 216 may have either a uniform flow profile where the flow per radial area across the substrate 126 is uniform or the gas flow can be preferential to the center or edge of the substrate 126, i.e. the gas flow may have a preferential flow profile.

The front and/or back surface of the transparent showerhead 214 and vacuum window 212 may be coated to have a band pass filter and to improve transmission of the desired wavelengths or improve irradiance profile of the substrate. For example, an anti-reflective coating (ARC) layer may be deposited on the transparent showerhead 214 and vacuum window 212 to improve the transmission efficiency of desired wavelengths. The ARC layer may be deposited in a way that the thickness of the reflective coating at the edge is relatively thicker than at the center region of the transparent showerhead 214 and vacuum window 212 in a radial direction, such that the periphery of the substrate disposed underneath the vacuum windows 212 and the transparent showerhead 214 receives higher UV irradiance than the center. The ARC coating may be a composite layer having one or more layers formed on the surfaces of the vacuum window 212 and transparent showerhead 214. The compositions and thickness of the reflective coating may be tailored based on the incidence angle of the UV radiation, wavelength, and/or the irradiance intensity.

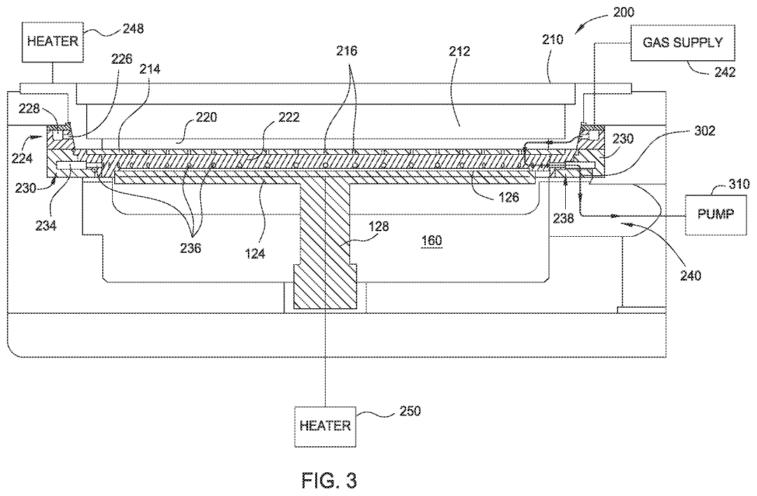

A gas distribution ring 224 made of aluminum oxide is positioned within the processing region 160 proximate to the sidewall of the UV chamber. The gas distribution ring 224 can be a single piece (not shown), or can include a gas inlet ring 223 and a base distribution ring 221 having one or more gas distribution ring passages 226. The gas distribution ring 224 is configured to generally surround the circumference of the vacuum window 212. The gas inlet ring 223 may be coupled with the base distribution ring 221 which together may define the gas distribution ring inner channel 228. A gas supply source 242 (FIG. 3) is coupled to one or more gas inlets (not shown) formed in a surface of the gas inlet ring 223 through which gas may enter the gas distribution ring inner channel 228. The one or more gas distribution ring passages 226 couple the gas distribution ring inner channel 228 with the upper processing region 220, forming a gas flow path between the inner channel 228 and the upper processing region 220 above the transparent showerhead 214.

A gas outlet ring 230 is positioned below the gas distribution ring 224 and may be at least partially below the transparent showerhead 214 within the processing region 160. The gas outlet ring 230 is configured to surround the circumference of the transparent showerhead 214 and having one or more gas outlet passages 236 coupling a gas outlet ring inner channel 234 and the lower processing region 222, forming a gas flow path between the lower processing region 222 and the gas outlet inner channel 234. The one or more gas outlet passages 236 of the gas outlet ring 230 are disposed at least partially below the transparent showerhead 214.

FIG. 3 depicts a schematic cross-sectional view of the process chamber 200 in FIG. 2 illustrating a gas flow path. As indicated by arrow 302, a processing gas such as the resist underlayer agent to be discussed below and/or other types of gases, may be injected into and evenly fill the upper processing region 220 between the vacuum window 212 and the transparent showerhead 214, through the transparent showerhead 214, over the substrate support 124 which may have a substrate 126 disposed thereon, down towards the substrate from the transparent showerhead 214. The gas flow washes over the substrate 126 from above, spreads out concentrically, and exits the lower processing region 222 through gas outlet passages 236. The gas then is ejected from the lower processing region 222, enters the gas outlet ring inner channel 234, and exits the gas outlet 238 into a gas exhaust port 240 and to a pump 310. Depending on the pattern of the passages 216 in the showerhead 214, the gas flow profile may be controlled across the substrate 126 to provide a desired uniform or non-uniform distribution.

In order to improve the efficiency of the dissociation, additional heater such as heaters 248, 250 shown in FIG. 2 may be used to heat other components in the processing chamber such as the vacuum window clamp 210, the gas distribution ring 224, and the substrate support 124.

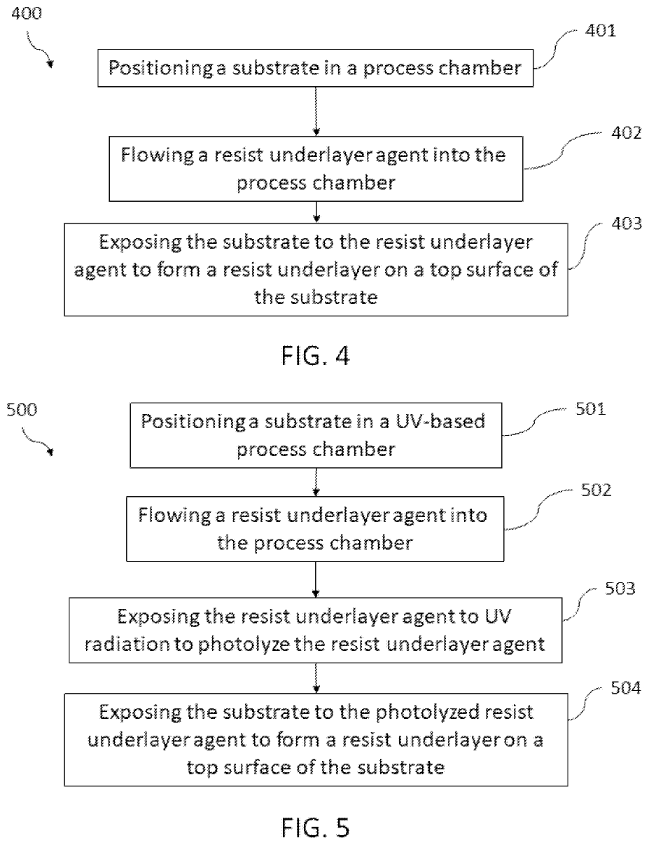

FIG. 4 illustrates an exemplary method 400 for forming a resist underlayer on a substrate. It should be noted that the sequence of steps illustrated in FIG. 4 are not intended to be limiting as to the scope of the present disclosure described herein, since one or more steps may be added, deleted and/or reordered without deviating from the basic scope of the disclosure.

The method 400 starts with operation 401 in which a substrate is positioned in a processing region of a process chamber. In some embodiments, the distance between the substrate and the showerheads of the process chamber may range from about 400 millimeters (mm) to about 1400 mm. In some embodiments, the process chamber may be a deposition chamber, configured to deposit materials onto a substrate using a vapor deposition process (thermal or plasma enhanced), such as atomic layer deposition (ALD), plasma enhanced ALD (PEALD), chemical vapor deposition (CVD), or plasma enhanced chemical vapor deposition (PECVD). In some embodiments, the process chamber may be a UV-based process chamber for forming the resist underlayer on the substrate using a UV assisted deposition process, as described below in method 500.

In some embodiments, method 400 may continue to operation 402 after disposing the substrate in the processing region of the process chamber such that the resist underlayer may be formed directly on a top surface of the substrate. In other embodiments, operation 402 may be performed after one or more interlayers are formed on the substrate such that one or more other interlayers may be disposed between the resist underlayer and the substrate.

Next, in operation 402, a resist underlayer agent is flowed into the processing region of the process chamber. In an embodiment, the resist underlayer agent may be flowed into the processing region with a carrier gas, such as He or Ar, which is inert with respect to processes occurring in the process chamber. The flow rate of the resist underlayer agent may be from about 100 milligrams per minute (mgm) to about 2000 mgm, for example about 1000 mgm. The flow rate of the carrier gas may be from about 500 standard cubic centimeters per minute (sccm) to about 5000 sccm, for example about 2000 sccm. The resist underlayer agent may also be delivered with or without heating. It is understood that the process conditions described herein are based on a 300 mm diameter substrate.

In some embodiments, the resist underlayer agent comprises a compound represented by formula (I):

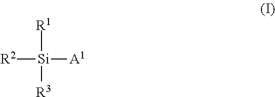

wherein R¹, R², and R³ are hydrocarbon functional groups with a general formula CₓH_{y} in which x has a range of between 1 and 8 and y has a range of between 1 and 17. In some embodiments, R¹, R², and R³ may all be the same functional groups or all different functional groups. In some embodiments, only some of R¹, R², and R³ may be the same functional groups. In some embodiments, R¹, R², and/or R³ may compromise alkyl, alkene, or alkyne groups with 1-8 carbon atoms and having linear, branched, or cyclic structures. In some embodiments, suitable hydrocarbon compounds for each of R¹, R², and R³ may include independently linear or branched C₁₋₈ alkyl, C₁₋₈ alkene, or C₁₋₈ alkyne groups.

In some embodiments, suitable hydrocarbon compounds for each of R¹, R², and R³ may independently include, but are not limited to, a methyl group (CH₃), an ethyl group (C₂H₅), a propyl group (C₃H₇), a butyl group (C₄H₉), an isobutyl group ((CH₃)₂CH CH₂), a tert-Butyl group ((CH₃)₃C), or an isopropyl group ((CH₃)₂CH).

In some embodiments, the resist underlayer agent according to formula (I) may be a silane where A¹ is a hydrogen atom. In other embodiments, the resist underlayer agent may be a silanamine where A¹ is an amine group.

In some embodiments, A¹ may be a primary amine group represented by formula (II):

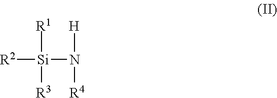

wherein R⁴ is a hydrocarbon functional group with a general formula CₓH_{y} in which x has a range of between 1 and 8 and y has a range of between 1 and 17, as described above with respect to R¹, R², and R³.

In other embodiments, A¹ may be a secondary amine group represented by formula (III);

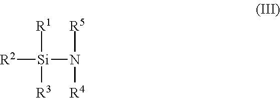

wherein R⁴ and R⁵ are hydrocarbon functional groups with a general formula CₓH_{y} where x has a range of between 1 and 8, and y has a range of between 1 and 17, as described above with respect to R¹, R², and R³. When A¹ is a secondary amine group, R⁴ and R⁵ may be the same hydrocarbon functional groups or different hydrocarbon functional groups.

In further embodiments, A¹ may be modified with other functional groups to achieve optimum interaction with corresponding functional groups in the EUV photoresist to be deposited thereon. For example, A¹ may comprise Cl, Br, I, or

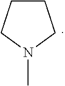

In one embodiment, an exemplary resist underlayer agent is represented by compound (IV) below:

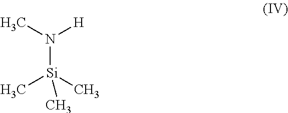

Next, the substrate in the processing region is exposed to the resist underlayer agent in operation 403, which may be in the form of a gas or a vaporized liquid vapor. During operation 403, the process chamber may be heated to a temperature of from about 40° C. to about 500° C., for example from about 200° C. to about 400° C., such as about 385° C. The chamber pressure may be from about 0.1 Torr to about 50 Torr, for example from about 0.5 Torr to about 20 Torr.

Operation 403 may be performed from about 15 seconds to about 900 seconds, for example about 60 seconds to form a resist underlayer on a top surface of the substrate (or one or more interlayers disposed thereon, if present). In some embodiments, the process time may be extended to improve coverage. In some embodiments, the resist underlayer may have a thickness less than about 50 nanometers, such as less than about 20 nanometers, such as less than about 10 nanometers, such as less than about 5 nanometers, such as less than or about 3 nanometers.

FIG. 5 illustrates an exemplary method 500 for forming a resist underlayer on a substrate using a UV-assisted deposition process, in accordance with certain embodiments of the present disclosure. The UV-assisted deposition process may be performed using any UV-based process chamber, such as the UV process chambers 100, 200 depicted in FIGS. 1 and 2. It should be noted that the sequence of steps illustrated in FIG. 5 are not intended to be limiting as to the scope of the present disclosure described herein, since one or more steps may be added, deleted and/or reordered without deviating from the basic scope of the disclosure.

Method 500 starts with operation 501 in which a substrate is positioned in a processing region of the UV-based process chamber in a manner as described above with respect to FIG. 3.

In some embodiments, method 500 may continue to operation 502 immediately after the substrate is disposed in the process chamber in operation 501 such that the resist underlayer may be formed directly on a top surface of the substrate. In other embodiments, operation 502 may be performed after one or more interlayers are deposited on the substrate prior to forming the resist underlayer such that one or more other interlayers may be disposed between the resist underlayer and the substrate.

In operation 502, a resist underlayer agent as discussed above with respect to method 400, is flowed into the UV-based process chamber. In an embodiment, the resist underlayer agent may be flowed into the processing region of the process chamber with a carrier gas, such as He or Ar, which is inert with respect to processes occurring in the process chamber.

The flow rate of the resist underlayer agent may be from about 100 milligrams per minute (mgm) to about 2000 mgm, for example about 1000 mgm. The flow rate of the carrier gas may be from about 500 standard cubic centimeters per minute (sccm) to about 5000 sccm, for example about 2000 sccm. In operation 502, the resist underlayer agent may be delivered with or without heating.

As discussed above, the processing region in the UV-based process chamber may be positioned such that UV radiation may be delivered through the windows 108 to facilitate photolysing of the resist underlayer agent, in operation 503. In operation 503, UV radiation is provided as the resist underlayer agent is flowed toward the substrate through a UV transparent gas distribution showerhead from a region between a UV transparent window and the UV transparent gas distribution showerhead, for example, the vacuum window 212 and the transparent showerhead 214 as discussed above with respect to FIGS. 2 and 3.

Operation 503 is performed by turning on an UV unit, such as UV lamp bulbs 122 shown in FIGS. 1 and 2, to assist dissociation of chemical bonds in the precursors of the resist underlayer agent. The UV unit may be turned on while or after the flowing of the resist underlayer agent into the UV-based process chamber. In some embodiments, the uniformity of UV radiation exposure may be tuned with spacing and rotating of the UV unit in the UV-based process chamber. In some embodiments, the power of the UV unit and the UV lamp bulbs 122 is about 12 KW. In some embodiments, the UV power output by the UV lamp bulbs 122 for operation 503 may be from about 1% to about 100%, such as between about 50% and about 90%, such as about 80%.

In operation 504, the substrate in the processing region is exposed to the resist underlayer agent, which may be in the form of a gas or a vaporized liquid vapor. During operation 504, the process chamber may be heated to a temperature from about 40° C. to about 500° C., for example from about 200° C. to about 400° C., such as about 385° C. The chamber pressure may be from about 0.1 Torr to about 50 Torr, for example from about 0.5 Torr to about 20 Torr.

Operation 504 may be performed from about 15 seconds to about 900 seconds, for example about 60 seconds to form a resist underlayer on a top surface of the substrate (or one or more interlayers disposed thereon, if present). In some embodiments, the process time may be extended to improve coverage. In some embodiments, the resist underlayer may have a thickness less than about 50 nanometers, such as less than about 20 nanometers, such as less than about 10 nanometers, such as less than about 5 nanometers, such as less than or about 3 nanometers.

The following non-limiting examples are provided to further illustrate implementations described herein. However, the examples are not intended to be all inclusive and are not intended to limit the scope of the embodiments described herein.

In some embodiments, advantages of the present disclosure provides for improved resist underlayer coverage and adhesion to the EUV photoresist deposited thereon. In one embodiment, as discussed above, the resist underlayer generally provides for improved adhesion with the EUV photoresist by increasing coverage and correspondingly increasing the reduction of the polar content of the substrate surface interacting with the photoresist. For example, as applied to when a resist underlayer is formed on a SiO₂ substrate, the hydrocarbon precursors of the resist underlayer react and bond with the polar OH molecules when the resist underlayer is deposited, thereby reducing the polar content of the substrate surface. Accordingly, the bonding by the hydrocarbon precursor with the polar OH molecules of the SiO₂ substrate may also be considered representative of the coverage by the resist underlayer with such coverage determined by measuring a corresponding change in carbon atom composition on the substrate surface after the resist underlayer is formed.

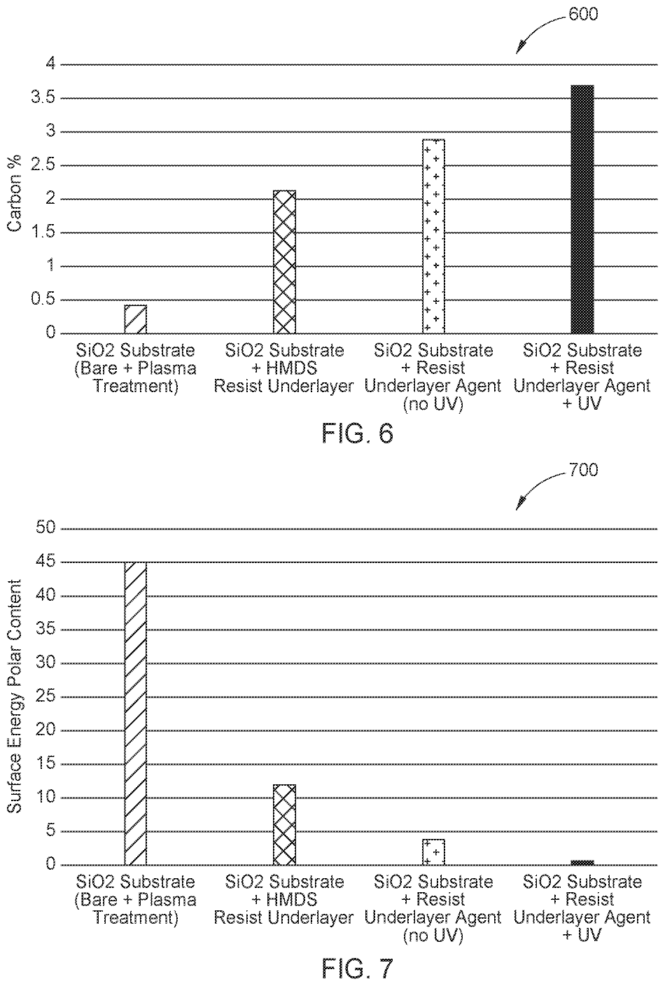

Resist underlayers were formed using methods 400 and 500 described above on a SiO₂ substrate surface. The surface composition of carbon atoms on a top surface of each of the resist underlayers were measured by surface XPS analysis to determine the extent of coverage by each of the respective resist underlayer as indicated by the % of hydrocarbon functional groups bonded on the substrate of the substrate. The results are shown in FIG. 6 with a graph 600 depicting carbon atom percentage composition measurements of the substrate surface for a plasma treated SiO₂ substrate, a SiO₂ substrate having a resist underlayer formed from precursors containing HMDS, and a SiO₂ substrate having a resist underlayer formed using the resist underlayer agent (with and without UV exposure).

As expected, the percentage of carbon content on the substrate surface dramatically increased when a resist underlayer was formed on the substrate surface. The measured carbon content of each of the resist underlayers (e.g., formed using HMDS and the resist underlayer agent) were greater than the carbon content of the plasma treated substrate. However, as compared between the resist underlayers formed via conventional means (e.g., flowing of HMDS precursor) and the resist underlayer agent, both of the resist underlayers formed using the resist underlayer agent (with and without UV exposure) exhibited even higher percentages of carbon atoms, indicating higher coverage on the substrate by the resist underlayer formed with precursors containing the resist underlayer agent. Regarding the resist underlayers formed using the resist underlayer agent, it was also observed that exposing the substrate to UV radiation during the deposition of the resist underlayer, as in operation 401 described above, yielded even higher percentages of carbon containing functional groups on the surface of the substrate. Exposure to UV radiation during the deposition process with the resist underlayer agent therefore assists in further increasing the resist underlayer coverage on the surface.

In some embodiments, the methods of the present disclosure also provides for forming a resist underlayer with surface energy modified with reduced polar content so as to increase adhesion at the interface between the resist underlayer and the EUV photoresist deposited thereon. For example, as shown in FIG. 7, a table 700 shows the polar content of each of the respective surfaces analyzed in FIG. 6 using surface energy data derived through contact angle measurements. Specifically, FIG. 7 shows a comparison of the corresponding polar surface energy portions of the substrate surface for a plasma treated SiO₂ substrate, a SiO₂ substrate having a resist underlayer formed using HMDS, and SiO₂ substrates having resist underlayers formed using the resist underlayer agent (with and without UV exposure).

Again, as expected, there was a great reduction in polar content on the analyzed substrate surface when a resist underlayer was formed on the surface of the substrate. As compared between the resist underlayer formed using HMDS and the resist underlayer agent, there was a greater reduction in the polar content of the surface energy of the substrate surface when the resist underlayer was formed using the resist underlayer agent. This greater reduction in polar content indicates a higher efficiency by the method of the present disclosure and the resist underlayer agent in eliminating polar groups on the substrate surface. Between the resist underlayers formed with the resist underlayer agent with and without UV exposure, there was a greater reduction in the polarity of the surface energy when the resist underlayer was formed with exposure to UV radiation (as in method 500), as compared to deposition of the resist underlayer with no UV radiation exposure (as in method 400).

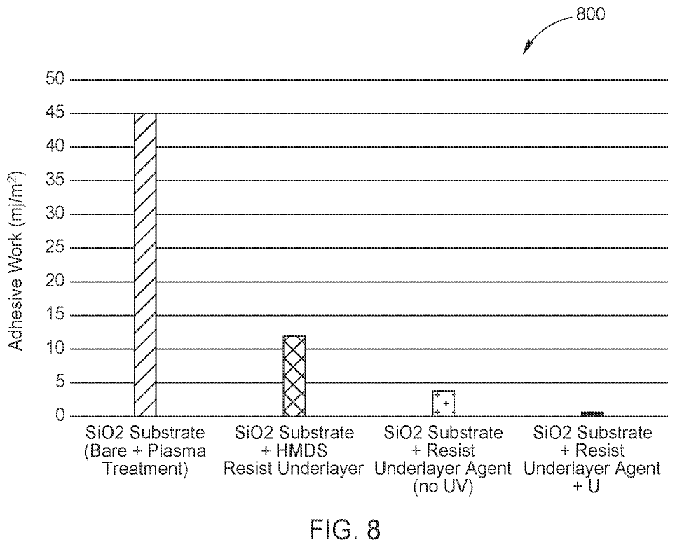

The greater coverage and reduction in surface energy polarity by the resist underlayer formed with the resist underlayer agent allows for increased photoresist adhesion. As discussed above, increased adhesion between the photoresist and the substrate surface can reduce the risk of pattern collapse. In some embodiments, the resist underlayer formed using the resist underlayer agent and exhibiting greater coverage on the substrate and greater reduction in surface energy polarity exhibited greater adhesive work, as shown in FIG. 8.

Adhesive work is an effective evaluation factor of underlayer-photoresist interaction since it takes surface energy of the photoresist (R), the liquid developer (L) and the resist underlayer on the substrate(S) into consideration. Adhesive work calculated based on surface free energy may be defined as the work needed to pull the EUV photoresist off the substrate in the developer solution. Therefore, a higher adhesive work indicates improvement in the adhesion between the EUV photoresist and the substrate. Adhesive work, W, can be estimated using the following equations:

$$W = {γ}_{RL} + {γ}_{SL} - {γ}_{RS}$$

$${γ}_{RL} = {( \sqrt{{γ}_{R}^{d}} \times \sqrt{{γ}_{L}^{d}} )}^{2} + {( \sqrt{{γ}_{R}^{p}} \times \sqrt{{γ}_{L}^{p}} )}^{2}$$

$${γ}_{SL} = {( \sqrt{{γ}_{S}^{d}} \times \sqrt{{γ}_{L}^{d}} )}^{2} + {( \sqrt{{γ}_{S}^{p}} \times \sqrt{{γ}_{L}^{p}} )}^{2}$$

$${γ}_{RS} = {( \sqrt{{γ}_{R}^{d}} \times \sqrt{{γ}_{S}^{d}} )}^{2} + {( \sqrt{{γ}_{R}^{p}} \times \sqrt{{γ}_{S}^{p}} )}^{2}$$

Where γ_{RL} is the interface force between the photoresist and the liquid developer, γ_{SL} is the interface force between the resist underlayer on the substrate and the liquid developer, γ_{RS} is the interface force between the photoresist and the resist underlayer on the substrate, and the surface free energy of the substrate γ_{SL} is calculated using contact angle measurements in two known surface free energy solvents.

FIG. 8 shows a table 800, which depicts the adhesive work for removing an EUV photoresist disposed on a substrate. In the examples shown, adhesive work was compared when the EUV photoresist was disposed directly on a SiO₂ substrate with no resist underlayer, and when resist underlayers formed using HMDS and the resist underlayer agent (with and without UV radiation assistance), were each disposed between the photoresist and the substrate. In the present example, adhesive work was measured when the photoresists and corresponding resist underlayers and/or substrates were immersed in a developer (e.g., Tetramethylammonium hydroxide (TMAH) 2.38% solution used as the developer). As shown, there was an increase in adhesive work when a resist underlayer (formed using either HMDS or the resist underlayer agent) was disposed between the photoresist and the substrate. Between the resist underlayers formed using HMDS and the resist underlayer agent, there is an appreciable increase in adhesive work for the resist underlayer formed using the resist underlayer agent (with or without UV radiation assistance). And as correlated with the results from FIGS. 6 and 7, there was a further increase in the adhesive work of the resist underlayer deposited using the resist underlayer agent with UV radiation exposure (as in method 500) than without UV radiation exposure (as in method 400).

Embodiments of the present disclosure use a resist underlayer agent to deposit a resist underlayer on a substrate. The resist underlayer formed on the substrate exhibits increase coverage with reduced polarity in the surface energy and increased adhesive work. As a result, adhesion between the resist underlayer and EUV photoresist deposited thereon is improved. Particularly, the resist underlayer agent used to form the resist underlayer contains a compound with a silicon atom bonded to three hydrocarbon functional groups and one amine group. Furthermore, the benefits provided by the resist underlayer deposited using the resist underlayer agent are further enhanced when the resist underlayer is deposited using a UV-assisted deposition process in a UV based process chamber. Use of a UV-assist deposition process to form the resist underlayer deposited enables forming single-molecular resist underlayers with tunable surface energy for varying precursors of the resist underlayer agent. The precursors of the resist underlayer agent may be tailored based on the EUV photoresist the resist underlayer is intended to be used with to increase the adhesion of the EUV photoresist to the underlayer resist. Accordingly, the present disclosure provides for improved adhesion of the resist underlayer to the EUV photoresist thereby improving line width roughness (LWR) and minimizing line pattern collapse (LPC) of the patterned EUV photoresist. The present disclosure also provides for decreasing the risk of LPC without decreasing the EUV photoresist thickness enabling the maintaining and/or increasing the etch resistance of the EUV photoresist.

While the foregoing is directed to embodiments of the present disclosure, other and further embodiments of the disclosure may be devised without departing from the basic scope thereof.

What is claimed is:

1. A method for forming a resist underlayer on a substrate, comprising:
exposing the substrate to a resist underlayer agent to form the resist underlayer over a top surface of the substrate, the resist underlayer agent comprising a chemical compound having a structure represented by formula I: 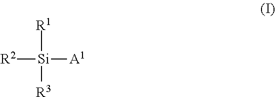
wherein R¹, R², and R³ are hydrocarbon functional groups each with a general formula CₓH_{y} in which x has a range of between 1 and 8, y has a range of between 1 and 17, and wherein A¹ is a hydrogen atom, chlorine atom, bromine atom, iodine atom, or an amine group.

2. The method of claim 1, wherein all or some of R¹, R², and R³ are the same hydrocarbon functional groups.

3. The method of claim 1, further comprising exposing the substrate and the resist underlayer agent to UV radiation to photolyse the resist underlayer agent.

4. The method of claim 1, wherein A¹ is an amine group comprising at least one hydrocarbon functional group with a general formula CₓH_{y} in which x has a range of between 1 and 8 and y has a range of between 1 and 17.

5. The method of claim 1, wherein A¹ is a primary amine group comprising a nitrogen atom bonded to a silicon atom, a hydrogen atom, and a carbon atom of a hydrocarbon functional group with a general formula CₓH_{y} in which x has a range of between 1 and 8 and y has a range of between 1 and 17.

6. The method of claim 1, wherein A¹ is a secondary amine group comprising a nitrogen atom bonded to a silicon atom, and carbon atoms of two hydrocarbon functional groups, wherein each of the two hydrocarbon functional groups comprise a general formula CₓH_{y} in which x has a range of between 1 and 8 and y has a range of between 1 and 17.

7. The method of claim 1, wherein the resist underlayer formed has a thickness less than about 50 nanometers, such as less than about 20 nanometers, such as less than about 10 nanometers, such as less than about 5 nanometers, such as less than or about 3 nanometers.

8. A method for forming a resist underlayer on a substrate, comprising:
exposing the substrate to UV radiation in an atmosphere of a resist underlayer agent to form the resist underlayer over a top surface of the substrate, the resist underlayer agent comprising a chemical compound having a structure represented by formula I: 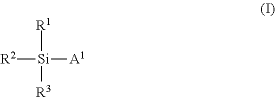
wherein R¹, R², and R³ are hydrocarbon functional groups each with a general formula CₓH_{y} in which x has a range of between 1 and 8 and y has a range of between 1 and 17, A¹ is a hydrogen or an amine group comprising at least one hydrocarbon functional group with a general formula CₓH_{y} in which x has a range of between 1 and 8 and y has a range of between 1 and 17.

9. The method of claim 8, wherein A¹ is a primary amine group comprising a nitrogen atom bonded to a silicon atom, a hydrogen atom, and one hydrocarbon functional group with a general formula CₓH_{y} in which x has a range of between 1 and 8 and y has a range of between 1 and 17.

10. The method of claim 8, wherein the resist underlayer formed has a thickness less than about 50 nanometers, such as less than about 20 nanometers, such as less than about 10 nanometers, such as less than about 5 nanometers, such as less than or about 3 nanometers.

11. A method for forming a resist underlayer over a substrate within a process chamber, comprising:
positioning the substrate in a processing region of the process chamber;
flowing a resist underlayer agent into the processing region, the resist underlayer agent comprising a chemical compound having a structure represented by formula I: 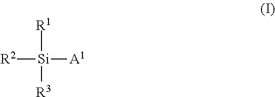
wherein R¹, R², and R³ are hydrocarbon functional groups each with a general formula CₓH_{y} in which x has a range of between 1 and 8 and y has a range of between 1 and 17, and A¹ is a hydrogen or an amine group; and
exposing the substrate to the resist underlayer agent to deposit the resist underlayer over a top surface of the substrate.

12. The method of claim 11, wherein exposing the substrate to the resist underlayer agent further comprises exposing the substrate to UV radiation in an atmosphere of the resist underlayer agent.

13. The method of claim 12, wherein exposing the substrate to UV radiation comprises setting the process chamber between with a UV power output from about 1% to about 100%.

14. The method of claim 11, wherein all or some of R¹, R², and R³ are the same functional groups.

15. The method of claim 11, wherein the resist underlayer agent is flowed with a carrier gas comprising He or Ar.

16. The method of claim 11, wherein a temperature in the process chamber is from about 40° C. to about 500° C.

17. The method of claim 11, wherein the resist underlayer agent is heated when flowing into the process chamber.

18. The method of claim 11, wherein the resist underlayer formed has a thickness less than about 50 nanometers, such as less than about 20 nanometers, such as less than about 10 nanometers, such as less than about 3 nanometers.

19. The method of claim 11, wherein A¹ is a primary amine group such that the resist underlayer agent comprises a structure represented by formula II: 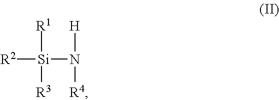
and
wherein R⁴ is a hydrocarbon functional group with a general formula CₓH_{y} in which x has a range of between 1 and 8 and y has a range of between 1 and 17.

20. The method of claim 11, wherein A¹ is a secondary amine group such that the resist underlayer agent comprises a structure represented by formula II: 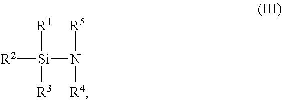
and
wherein R⁴ and R⁵ are hydrocarbon functional groups each with a general formula CₓH_{y} in which x has a range of between 1 and 8 and y has a range of between 1 and 17.
